(19) United States
(12) Patent Application Publication
(10) Pub. No.: US 2020/0381894 A1
(43) Pub. Date: Dec. 3, 2020

(54) Uniform Cooling of Laser Diode

(71) Applicant: Trumpf Photonics, Inc., Cranbury, NJ (US)

(72) Inventor: Hans-Georg Treusch, Tucson, AZ (US)

(21) Appl. No.: 16/428,676

(22) Filed: May 31, 2019

(51) Int. Cl. H01S 5/024; H01S 5/022

(52) U.S. Cl. CPC H01S 5/02469; H01S 5/4025; H01S 5/02256; H01S 5/02423

(57) ABSTRACT

In general, in some aspects, the subject matter of the present disclosure encompasses laser diode heat sinks that include: multiple planar foils, in which each planar foil of the multiple planar foils includes a first face and a second face opposite the first face, the multiple planar foils being arranged in a stack along a stacking direction, with the second face of each planar foil of the plurality of planar foils arranged on a first face of a respective preceding planar foil in the stack. The first face of each planar foil of the multiple planar foils includes a corresponding elongated trench extending substantially along a second direction that is perpendicular to the stacking direction, and, for each planar foil of the multiple planar foils, a depth of the corresponding trench extends through less than an entire thickness of the planar foil.

### TECHNICAL FIELD

The present disclosure relates to uniform cooling of laser diodes.

### BACKGROUND

Laser diodes generate heat during operation. In various applications, it is useful to mount the laser diodes to a heat sink to remove the heat generated by the laser diodes and maintain efficient operation of the laser diodes.

### SUMMARY

In general, in some aspects, the subject matter of the present disclosure encompasses laser diode heat sinks that include: multiple planar foils, in which each planar foil of the multiple planar foils includes a first face and a second face opposite the first face, the multiple planar foils being arranged in a stack along a stacking direction, with the second face of each planar foil of the plurality of planar foils arranged on a first face of a respective preceding planar foil in the stack. The first face of each planar foil of the multiple planar foils includes a corresponding elongated trench extending substantially along a second direction that is perpendicular to the stacking direction, and, for each planar foil of the multiple planar foils, a depth of the corresponding trench extends through less than an entire thickness of the planar foil.

Implementations of the laser diode heat sinks disclosed herein may include one or more of the following features. For example, in some implementations, a first side of the stack provides a laser diode mounting region, in which, for each planar foil of the multiple planar foils, a portion of the trench extends in the second direction substantially alongside the laser diode mounting region.

In some implementations, the stack includes a common fluid inlet port to which the corresponding trench of each planar foil of the multiple planar foils is fluidly coupled, in which the common fluid input port extends through the stack along the stacking direction. The stack may include a common fluid output port to which the corresponding trench of each planar foil of the multiple planar foils is fluidly coupled. The common fluid output port may extend through the stack along the stacking direction.

In some implementations, the stack includes: at least two common fluid inlet ports to which the corresponding trench of each planar foil of the plurality of planar foils is fluidly coupled; and a common fluid output port to which the corresponding trench of each planar foil of the plurality of planar foils is fluidly coupled, in which each of the at least two common fluid input ports and the common fluid output port extends through the stack along the stacking direction.

In some implementations, the laser diode heat sink includes a dielectric layer on the first side of the stack. The dielectric layer may include an aluminum nitride layer. The laser diode heat sink may include at least one laser diode mounting pad on the dielectric layer. The at least one laser diode mounting pad may include a metal layer. The laser diode heat sink may include multiple laser diode mounting pads, in which each laser diode mounting pad of the multiple laser diode mounting pads is separated from an adjacent laser diode mounting pad by a corresponding gap. Each gap may be elongated along the first side of the stack in the stacking direction.

In some implementations, for each planar foil of the multiple planar foils, the depth of the trench is less than or equal to about 150 microns. A width of the trench may be less than or equal to about 1 mm.

In some implementations, for each planar foil of the multiple planar foils, the thickness of the planar foil is less than or equal to about 300 microns.

In some implementations, the multiple planar foils in the stack are aligned on top of one another so that the trench of each foil is aligned with and overlaps with a trench of an adjacent planar foil in the stack.

In some implementations, for each planar foil of the multiple planar foils, the trench has a bottom surface defined by the planar foil in which the trench is formed and a top surface defined by a face of an adjacent planar foil in the stack.

In some implementations, each planar foil of the multiple planar foils is a copper foil.

In some implementations, the multiple planar foils are welded together.

In general, in some other aspects, the subject matter of the present disclosure may be embodied in laser diode apparatuses including: a first heat sink; a second heat sink; and at least one laser diode mounted between the first heat sink and the second heat sink, in which each of the first heat sink and the second heat sink includes a corresponding multiple of foils arranged in a stack along a first direction. Each foil of the multiple of foils in the first heat sink and in the second heat sink includes a generally planar first face and a generally planar second face opposite the first face with the second face of each foil arranged on a face of a respective preceding foil in the stack. The first face of each foil of the multiple foils in the first heat sink and in the second heat sink includes a corresponding elongated trench, and, for each foil of the multiple foils in the first heat sink and in the second heat sink, a depth of the corresponding trench extends through less than an entire thickness of the foil.

In general, in some aspects, the subject matter of the present application may be embodied in methods of forming a laser diode heat sink, in which the methods include: providing multiple foils, each foil of the multiple foils including a generally planar first face and a generally planar second face opposite the first face, and a distance between the first face and the second face defining a thickness of the foil. The methods further include forming in the first face of each foil of the multiple foils, a corresponding trench, in which a depth of the corresponding trench extends through less than the thickness of the foil. The methods further include mounting the multiple foils together into a stack along a first direction, with the second face of each foil of the plurality of foils arranged on a face of a respective preceding foil in the stack. For each foil of the multiple foils, the trench extends substantially along a second direction that is perpendicular to the first direction.

Implementations of the methods may include forming at least one common fluid input port in the stack, in which the corresponding trench of each foil of the multiple foils is fluidly coupled to the at least one common fluid input port, and the at least one common fluid input port extends through the stack along the first direction. Implementations of the methods may include forming at least one common fluid output port in the stack, in which the corresponding trench of each foil of the multiple foils is fluidly coupled to the at least one common fluid output port, and the at least one common fluid output port extends through the stack along the first direction.

Various implementations of the devices and methods disclosed herein may include one or more of the following advantages. For example, in some implementations, the laser diode heat sinks can be used to establish substantially uniform temperature along the laser diode devices, which in turn can allow the laser diode devices to maintain narrow wavelength distributions in the light output. In some implementations, the laser diode heat sinks disclosed herein allow large differences between inlet and outlet coolant temperatures and thus increased heat transfer. In some implementations, the laser diode heat sinks disclosed do not require a mounting area that is substantially larger than the laser diode arrays that are mounted to the heat sinks. For example, in some cases, the mounting area can be 101%, 102%, 103%, 104%, or 105% of the footprint of the laser diode array mounted to the heat sinks. In some implementations, coolant flow in a first laser diode heat sink propagates in one direction relative to a laser diode array mounted to the heat sink whereas coolant flow in a second laser diode heat sink propagates in a second opposite direction relative to the laser diode array thus allowing temperature uniformity across the laser diode array to be improved even when inlet and outlet coolant temperatures differs by more than 5 degrees C.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a schematic illustrating a perspective view of an example of a laser diode heat sink.

FIG. 2 is a schematic illustrating a side view of an example of a laser diode heat sink.

FIG. 3A is a schematic that illustrates an exploded view of an example of a laser diode heat sink stack.

FIG. 3B is a schematic that illustrates a perspective view of exemplary planar foils combined together to form a stack of a laser diode heat sink.

FIG. 4 is a schematic illustrating a perspective view of an example of double-sided heat sink mounting of laser diodes.

FIG. 5 is a schematic that illustrates a side view of an exemplary planar foil.

FIG. 6 is a schematic that illustrates a perspective view of an example of double-sided heat sink mounting of laser diodes and a fluid manifold coupled to the laser diode heat sinks.

### DETAILED DESCRIPTION

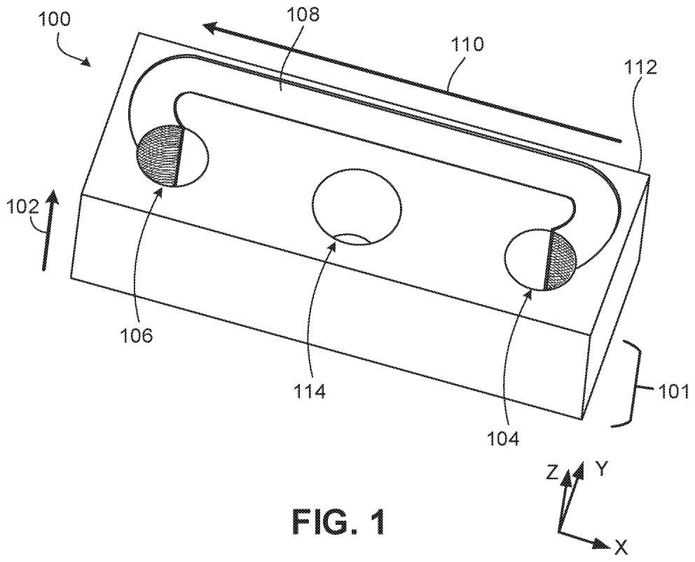

FIG. 1 is a schematic illustrating a perspective view of an example of a laser diode heat sink 100, The laser diode heat sink 100 is formed as a stack 101 of multiple planar foils, which are stacked along a stacking direction 102 (e.g., along a direction parallel to the Z-axis as shown in FIG. 1). As stacked, the laser diode heat sink 100 includes at least one fluid input port 104 and at least one fluid output port 106. Each of the fluid input ports 104 and the fluid output ports 106 includes an opening that extends through the stack 101 along the stacking direction 102. Though the fluid input ports 104 and fluid output ports 106 are shown as extending entirely through the stack, it is possible in some implementations that the fluid input port 104 and/or fluid output port 106 extend partially through the stack 101, i.e., not all the way through the stack. Additionally, though the ports 104, 106 are referred to herein as “fluid input” and “fluid output,” these terms are interchangeable and do not depend on the particular location of the port. For example, port 104 could be a fluid output port and port 106 could be a fluid input port.

A first side of each planar foil in the stack 101 includes a corresponding elongated trench 108. Only the trench 108 for a first planar foil is shown in FIG. 1, though the faces of other planar foils in the stack 101 also include corresponding trenches. A depth of the elongated trench 108 of each planar foil in the stack 101 extends through less than an entire thickness of the planar foil in which the trench is formed. For example, for the heat sink 100 shown in FIG. 1, a thickness of each planar foil may be understood as being defined along the Z-axis. The trench 108 of the first planar foil shown in FIG. 1 also has a depth defined along the Z-axis that is less than the thickness of the planar foil in which it is formed.

For each planar foil in the stack 101, the trench formed in the foil extends substantially along a second direction 110. The second direction 110 may be perpendicular to the stacking direction 102. For example, as shown in FIG. 1, the second direction is parallel with the X-axis.

The fluid input port 104 is a common port for a first opening into each of the trenches of the planar foils. That is, a first side of each trench may be fluidly connected to the fluid input port 104 so that when fluid is introduced into fluid input port 104, the fluid enters each of the trenches. Similarly, the fluid output port 106 is a common port for a second opening into each of the trenches of the planar foils. That is, a second side of each trench may be fluidly connected to the fluid output port 106 so that when fluid exits the trenches, the fluid from each of the trenches enters into the fluid output port 106. Each of the fluid input port 104 and the fluid output port 106 may have an opening size in the range of, e.g., about 2 to about 11 mm², including, e.g., between about 4 to about 9 mm².

A first side 112 of the stack 101 forms a laser diode mounting region. For example, as shown in FIG. 1, the laser diode mounting region 112 corresponds to a plane that is parallel to an area defined by the Z-X axes. The laser diode mounting region 112 is on a side of the stack 101 nearest to the elongated portions of each of the trenches that are formed in the planar foils. In this way, as fluid is transported through the trenches, the fluid can absorb heat generated by laser diodes mounted to the stack 101, allowing the laser diodes to cool and improve their efficiency of operation. For example, a coolant fluid may be supplied to fluid input port 104, propagate through the trenches 108 of each of the planar foils that make up stack 101, absorb heat from laser diodes mounted to the heat sink 100, and then be extracted at fluid output port 106.

In some implementations, the stack 101 may include at least one mounting hole 114. Mounting hole 114 may be formed by creating an opening in each of the planar foils. A mounting hole 114 may receive a mounting component that allows the stack 114 to mount to a fluid manifold that provides the coolant fluid to the fluid input port 104 and receives fluid from the fluid output port 106. For example, an internalsurface of mounting hole 114 may be threaded to receive a screw.

In some implementations, the planar foils of heat sink 100 are stacked so that the trenches 108 of each planar foil are aligned with one another in directions normal to the stacking direction. For example, the trenches 108 of the heat sink 100 are aligned with one another in the X and Y directions so that, if one could view each planar foil within the stack 101 along the Z-direction, it would appear as if the footprint of each trench 108 directly overlaps one another.

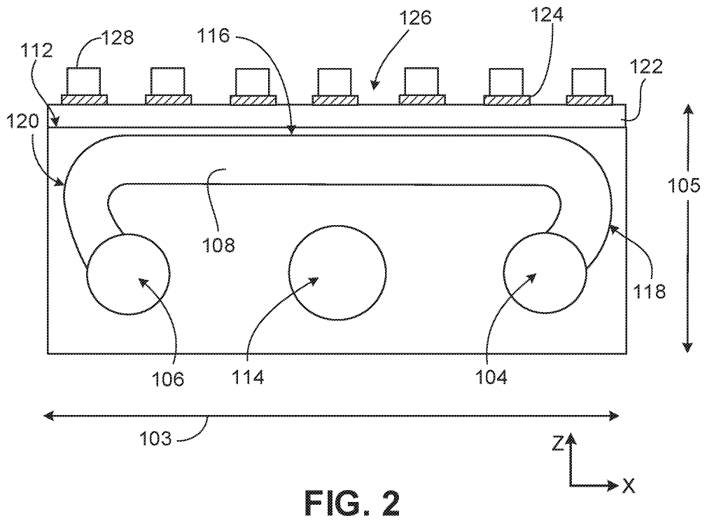

FIG. 2 is a schematic illustrating a side view of an example of the laser diode heat sink 100. The side view illustrates a surface of one of multiple planar foils that form the stack 101 of the heat sink. Each planar foil in the stack 101 may have a corresponding length 103 (e.g., as shown extending along the X-axis in FIG. 2), a corresponding width (e.g., as shown extending along the Z-axis in FIG. 2), and corresponding thickness (e.g., extending along the Y-axis). The length 103 may be in the range of, e.g., about 5 mm to about 50 mm, including, e.g., about 10 mm, about 12 mm, about 14 mm, about 16 mm, about 18 mm, about 20 mm, about 25 mm, about 30 mm, about 35 mm, about 40 mm, or about 45 mm, among other lengths. The width 105 may be in the range of about 1 mm to about 20 mm; including e.g., about 2 mm, about 3 mm, about 4 mm, about 5 mm, about 8 mm, about 10 mm, about 12 mm, about 14 mm, about 16 mm, or about 18 mm, among others. The depth of each foil 108 may be in the range of about 100 microns to about 1 mm including, e.g., about 200 microns, about 300 microns, about 400 microns, about 500 microns, about 600 microns, about 700 microns, about 800 microns; or about 900 microns, among others. As an example, the depth of each foil 108 may be less than or equal to about 300 microns.

As shown in the example, the heat sink 100 includes the fluid input port 104, the fluid output port 106 and the mounting hole 114. Also shown is the trench 108 in a first planar foil of the heat sink stack 101. As explained herein, each trench may include a first portion that extends substantially along a laser diode mounting region. For example, as shown in FIG. 2, heat sink has a laser diode mounting region 112 formed by surfaces of the planar foils in the stack 101. A first portion 116 of each trench 108 extends substantially along the laser diode mounting region 112. The length of the first portion 116 may extend along substantially the entire side of the planar foil. For example, the length of portion 116 may be slightly less than the total length 103 of the planar foil such as, e.g., about 2 mm less, about 1 mm less, about 500 microns less, or about 250 microns less than the length 103.

In some implementations, trenches 108 also include other portions that do not extend along the laser diode mounting region 112. For example, as shown in FIG. 2, trench 108 includes a second portion 118 that extends to the fluid input port 104, e.g., along the Z-axis. Trench also includes a third portion 120 that extends to the fluid output port 106 along the Z-direction. The length of the second portion 118 and the third portion 120 may extend at least partially along the width 105 of the planar foil. For example, in some implementations, the length of the second portion 118 and/or third portion 120 may be between about 1 mm and about 20 mm, including, for example, about 2 mm, about 4 mm, about 6 mm, about 8 mm, about 10 mm, or about 12 mm. In some implementations, trench 108 only includes the first portion that extends substantially along the laser diode mounting region 112. For example, the fluid input port 104 may be formed directly at first end of the first portion 116, whereas the fluid output port 106 may be formed directly at a second end of the first portion 116, directly opposite the first end.

Each trench 108 may have a corresponding width defined along a direction that is transverse to fluid flow through the trench. For example, each trench 108 may have a width that is between about 100 microns to about 1 mm including, e.g., about 200 microns, ab out 300 microns, about 400 microns, about 500 microns, about 600 microns, about 700 microns, about 800 microns, or about 900 microns, among others.

The laser diode mounting region 112 provides a surface on which at least one laser diode may be mounted. In some implementations, an insulating layer is formed on the laser diode mounting region 112 to prevent the laser diodes from electrically shorting with the laser diode heat sink. For example, as shown in FIG. 2, a dielectric layer 122 may be formed on the laser diode mounting region 112, The dielectric layer can include, e.g., electrically insulating dielectrics such as silicon dioxide, silicon nitride, aluminum nitride, among other types of insulating dielectrics including dielectrics having high thermal conductivity and high electrical resistance. The dielectric layer may have thicknesses in the range of, e.g., about 0.05 mm to about 0.5 mm including, e.g., between about 0.1 mm to about 0.4 mm.

A top surface of the dielectric layer 122 may include multiple carrier mounting pads 124 (also referred to herein as laser diode mounting pads). The carrier mounting pads 124 provide surfaces on which individual laser diode bars may be mounted and, in some implementations, electrically connected. The carrier mounting pads 124 may be formed from a metal such, as, e.g., copper. The carrier mounting pads 124 are elongated to fit at least a footprint of a laser diode bar that will be mounted to the pad 124. For example, the mounting pads 124 in FIG. 2 may be elongated in the Y-axis direction. In some implementations, the length of the elongated portion of the carrier mounting pad 124 may be substantially equal to the depth of the stack 101. For example, in some instances, the length of the elongated portion of the carrier mounting pad 124 may be between about 1 mm and about 10 mm including, e.g., about 2 mm, about 3 mm, about 4 mm, about 5 mm, about 6 mm, about 7 mm, about 8 mm, or about 9 mm, along the Y-axis direction, among others. The width of each carrier mounting pad 124 (e.g., along the X-axis direction) may be in the range of, e.g., between about 100 microns to about several millimeters, including, e.g., between about 200 microns to about 4 mm. Each carrier mounting pad 124 may have a thickness (e.g., as determined along the Z-axis direction) that is in the range of, e.g., about 500 nm to about 300 microns including, e.g., between about 1 micron to about 200 microns. Each carrier mounting pad 124 is separated from an adjacent carrier mounting pad 124 by a corresponding gap 126. A width of each gap 126 (e.g., along the X-axis direction) may be in the range of, e.g., about 50 microns to about 200 microns. A separate laser diode bar 128 may be formed on each carrier mounting pad 124. In some implementations, a footprint of each laser diode bar 128 fits within the surface area of the carrier mounting pad 124.

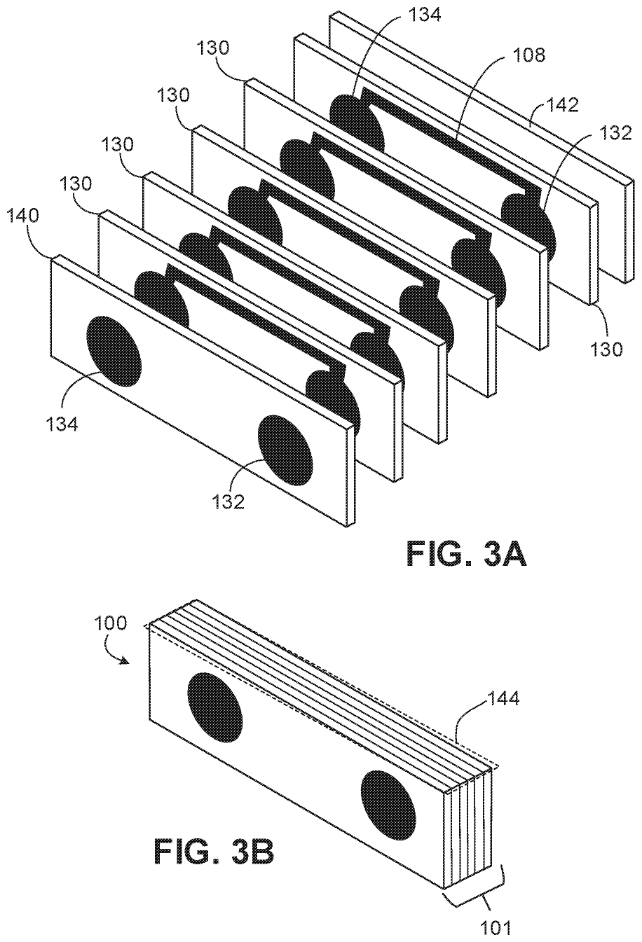

FIG. 3A is a schematic that illustrates an exploded view of an example of the laser diode heat sink stack. As shown in FIG. 3A, the stack includes multiple planar foils 130. The planar foils 130 may be formed from a material having a high thermal conductivity to improve heat transfer, such as copper. In some implementations, the total number of planar foils 130 that make up a stack 101 is between about 5 to about 50 including, e.g., about 10 foils, about 15 foils, about 20 foils, about 25 foils, about 30 foils, about 35 foils, about 40 foils, or about 45 foils, among others. The planar foils 130 may have a corresponding length, width and depth as described herein. Each planar foil 130 also may include a corresponding trench 108 as described herein.

As explained herein, the depth of each trench 108 does not extend all the way through the thickness of the foil. Instead, a bottom surface of each trench 108 is defined by the foil in which the trench 108 is formed. Similarly, the sidewalls of each trench 108 are defined by the foil in which the trench 108 is formed. However, the top surface of each trench 108 is defined by the surface of an adjacent foil in the stack. The depth of each foil 108 may be in the range of about 50 microns to about 500 microns including, e.g., about 100 microns, about 200 microns, about 300 microns, or about 400 microns, among others. In some implementations, the depth of each trench 108 is not greater than half the thickness of the foil 130 in which the trench 108 is formed, though the depth may be less than half the thickness of the foil 130. For example, the depth of each foil 108 may be less than 200 microns, including, e.g., less than 150 microns. The trenches 108 may be formed in each planar foil 130 by performing an etch, e.g., by performing a patterned wet etch or by performing a patterned dry etch.

Each foil 130 may include a first hole 132 that extends all the way through the thickness of the foil 130, as well as a second hole 134 that extends all the way through the thickness of the foil. When the foils 130 are combined together into the stack 101, the holes 132 combine together to form the fluid input port, whereas the holes 134 combine together to form the fluid output port. The holes 130, 132 may be formed by performing an etch of the foil, e.g., by performing a patterned wet etch or a patterned dry etch. In some implementations, the trench pattern and holes 132, 134 formed in planar foils 130 are substantially identical.

In some implementations, the heat sink 100 includes a planar foil 140 that forms a front foil or front surface of the stack 101. The front foil 140 may have the same overall dimensions and be formed as the same material as the other foils 130 in the stack 101. The front foil 140 does not include a trench 108 but rather serves as a cover for the trench 108 of a directly adjacent foil 130 in the stack. The front foil 140 may still include openings 132, 134 to form part of the fluid input and output ports. In some implementations, the heat sink 100 includes a planar foil 142 that forms a rear foil or rear surface of the stack 101. The rear foil 142 may have the same overall dimensions and be formed as the same material as the other foils 130 in the stack 101. The rear foil 140 may not include a trench 108. The rear foil 140 may still include openings to form part of the fluid input and output ports.

FIG. 3B is a schematic that illustrates a perspective view of the foils 130 combined together to form the stack 101 of the laser diode heat sink 100. When stacked together, a top surface 144 (whose perimeter is identified by the dashed lines in FIG. 3B) serves as the laser diode mounting surface on which the insulating layer, carrier mounting pads and laser diode bars may be formed. To form the stack 101, the planar foils 130, 140, 142 may be welded together. For example, in the case the foils are formed from copper, which has a melting point of close to about 1098 degrees centigrade, the planar foils may be stacked together and then heated in an oven that reaches about 1073 degrees centigrade. Welding under such conditions may require only several minutes. An advantage of forming the trenches only partially through each planar foil 130 is that it allows an increase in cooling capacity relative to other types of laser diode heat sink structures. For example, in some types of laser diode heat sinks that include cooling fins, the width of the fins are restricted to at least 250 microns in width because the welding process would otherwise cause the fins to melt together if their widths were smaller. In such cases, only a limited number of fins can be formed in the device close to the mounting surface 112, limiting its cooling capacity. In contrast, with the presently described structure, welding of the planar foils together does not lead to the trenches being melted together, therefore allowing the trench depth to be reduced, and a greater number of cooling trenches (and thus greater surface area for cooling) to be formed in the heat sink.

The laser diode heat sink 100 shown in FIGS. 1-3 only provides cooling to one side of the laser diode bars when the laser diode bars are mounted to the heat sink. In some implementations, a second separate heat sink may be positioned above and mounted to the laser diode bars. The second separate heat sink then provides cooling to a second opposite side of the laser diode bars. Cooling the first and second sides of the laser diode bars can, in certain implementations, ensure a more uniform cooling of the laser diodes during operation.

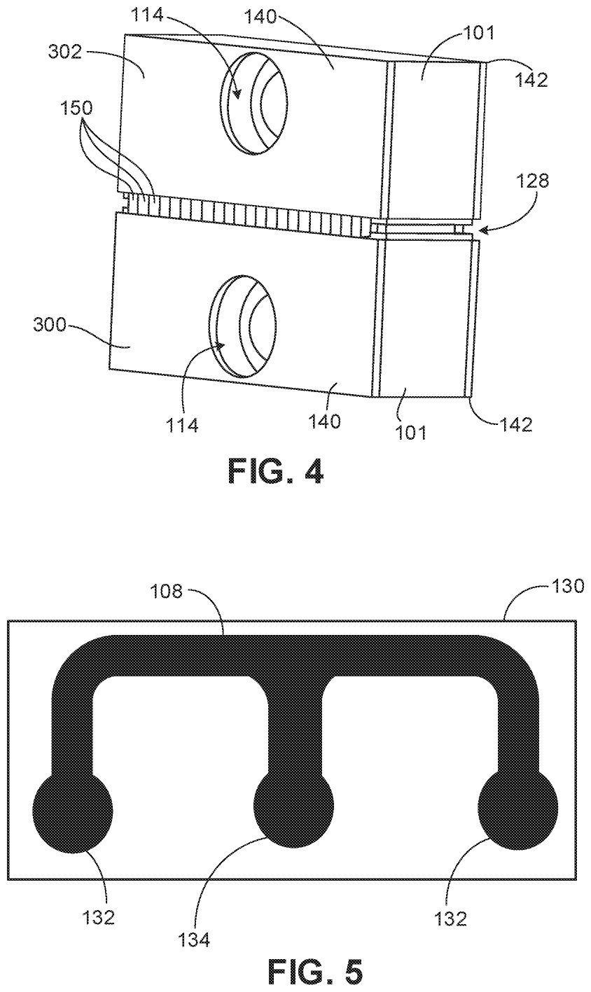

FIG. 4 is a schematic illustrating a perspective view of an example of double-sided heat sink mounting of laser diode bars. As shown in FIG. 4, a plurality of laser diodes 128 are mounted to a first heat sink 300. Each of first heat sink 300 and second heat sink 302 can include any of the heat sinks as described herein. For example, both first heat sink 300 and second heat sink 302 can include corresponding stacks 101 of planar foils, in which each planar foil of the stacks 101 includes a corresponding fluid trench having a depth that is less than the thickness of the foil in which it is formed. Each foil of the stacks 101 may also include a corresponding inlet hole and outlet hole coupled to the trench such that when the planar foils are stacked together, the inlet holes form a fluid inlet port coupled to all of the trenches of the foils, and the outlet holes form a fluid outlet port coupled to all of the trenches of the foils. For ease of illustration, inlet and output fluid ports are not shown in FIG. 4. In some implementations, one or both of heat sinks 300, 302 include corresponding mounting holes 114 through which mounting structures, such as screws may be inserted.

Each of heat sinks 300, 302 also may include corresponding front planar foils 140 and rear planar foils 142 on the front and back surfaces of stacks 101. The front and/or rear planar foils 140, 142 may include inlet holes, outlet holes, and mounting holes, but may not include fluid trenches that are formed within their planar surfaces.

As explained with respect to FIG. 2, the laser diode bars 128 may be individually mounted to corresponding carrier mounting pads that are, in turn, formed on an insulating layer on the laser diode mounting surface of the heat sink. For instance, in some cases, a cathode (or anode) of each laser diode bar 128 may be mounted to and electrically connected to a corresponding carrier mounting pad formed as part of heat sink 300. In some cases, an anode (or cathode) of each laser diode bar 128 may be mounted to and electrically connected to a corresponding mounting pad formed as part of heat sink 302.

In some implementations, multiple optical elements may be positioned in front of the light emitting surfaces, respectively, of the laser diode bars mounted to the heat sinks. The optical elements can include optical elements that are configured to refract the light emitted from the laser diode bars, such as lenses, e.g., convex lenses or concave lenses. For example, as shown in FIG. 4, multiple cylindrical lenses 150 are formed in front of multiple laser diodes 128, respectively. Light that is emitted by the laser diode bars 128 then is shaped and/or redirected by the optical elements. Although shown as multiple optical elements in the example of FIG. 4, a single optical element may be mounted in front of the light emitting surfaces of multiple laser diode bars. Optical elements other than lenses may be used in some implementations. For example, in some instances, the optical elements may include prisms, mirrors or filters, such as interference filters. In some implementations, the optical elements are mounted to one or both heat sinks 300, 302. For example, the optical elements may be bonded using a lens bonding cement that bonds the optical element to, e.g., the insulating layer of the laser diode mounting regions of the heat sinks, Although the optical elements 150 shown in FIG. 4 are illustrated as being provided in a device that includes both a first and second heat sink, optical elements can be provided in a device that includes a single heat sink.

Although the examples shown in FIGS. 1-3 illustrate a single fluid input port and a single fluid output port formed in the laser diode heat sink, it is possible to provide multiple fluid input ports, multiple fluid output ports and/or multiple fluid input and multiple fluid output ports. As an example, FIG. 5 is a schematic that illustrates a side view of an exemplary planar foil 130 that includes two fluid inlet holes 132 and a single fluid output outlet hole 134. Each of the fluid inlet holes 132 and the fluid outlet hole 134 are formed so as to extend entirely through a thickness of the planar foil 130. The fluid inlet and outlet holes also couple to a trench 108 formed in a surface of the planar foil 130. When multiple planar foils 130 having the configuration shown in FIG. 5 are stacked together to form a laser diode heat sink, the inlet holes form fluid inlet ports through which a coolant can be provided, and the outlet holes form a fluid outlet port out of which the coolant can be extracted. Thus, during operation of a heat sink formed from a stack of the planar foils shown in FIG. 5, coolant may enter through both holes 132, traverse the trench 108, which is located beneath a laser diode mounting region, and then exit through hole 134. The fluid inlet holes and outlet holes may have the same dimensions as the inlet and outlet holes described in the other examples herein. Though the example shown in FIG. 5 includes a single fluid outlet hole, any of the holes can be a fluid inlet hole or a fluid outlet hole depending on the configuration of the system coupled to the heat sink and providing the coolant.

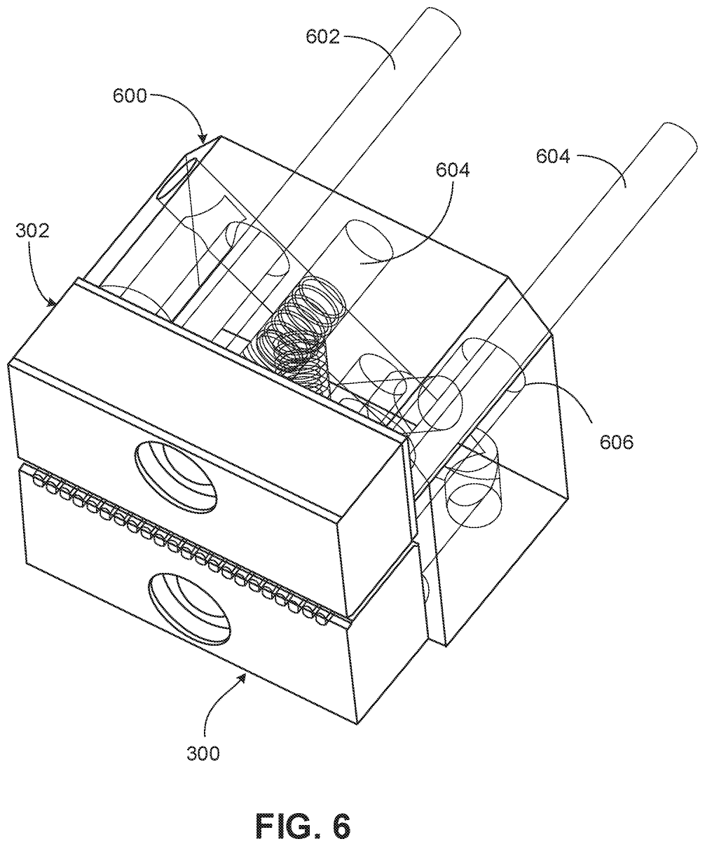

In some implementations, a fluid manifold may be mounted to the heat sink described herein to provide and extract the coolant fluid. In some cases, e.g., when two heat sinks are used, a fluid manifold may be mounted to both heat sinks. For instance, FIG. 6 is a schematic that illustrates an example of a first heat sink 300 as described herein, a second heat sink 302 as described herein, and a fluid manifold 600 attached to both the first and second fluid heat sinks. The fluid manifold 600 may include a block, such as a metal or plastic block, in which multiple openings are formed. One or more of the openings 604 may include a recess having threaded interior walls for receiving a mounting screw. One end of a mounting screw may be received by the opening 604, whereas another end of the mounting screw may be received by a mounting hole in the heat sink 302. Similarly, another opening 604 in the manifold 600 may receive a first end of a second screw, whereas a second end of the second screw may be received by a mounting hold in the other heat sink 300. The fluid manifold 600 also may include multiple openings 606. Each opening 606 may be aligned with a corresponding fluid input port or fluid output port in either the heat sink 300 or heat sink 302. The openings 606 may be coupled to the fluid input ports and/or fluid output ports using, e.g., gaskets or other type of seal to ensure that there is no fluid leakage between the heat sinks and the fluid manifold 600. During operating of the system, a coolant fluid, e.g., water, may be provided through the fluid manifold as input fluid 602. The input fluid 602 travels through one or more fluid input ports of the heat sinks 300, 302. After entering the fluid input ports, the coolant fluid passes into the trenches formed within the stacks of the laser diode heat sinks, where the coolant fluid absorbs heat generated by the laser diodes mounted on one or both of the heat sinks 300. The coolant fluid then propagates out of fluid output ports formed in one or both heat sinks 300, 302 and then back into the fluid manifold 600 where the heated fluid may be dispenses or re-cooled. In some implementations, the fluid manifold can be set up so that the coolant fluid is introduced into the upper heat sink 302 so that it travels in one direction relative to the laser diode array (e.g., left to right across the array of laser diodes) whereas coolant fluid may be introduced into the lower heat sink 300 so that it travels in a second opposite direction relative to the laser diode array. In this way, temperature uniformity across the laser diodes of the laser diode array can be improved.

A number of embodiments of the invention have been described. Nevertheless, it will be understood that various modifications may be made without departing from the spirit and scope of the invention. Accordingly, other embodiments are within the scope of the following claims.

What is claimed is:

1. A laser diode heat sink comprising:
a plurality of planar foils, wherein each planar foil of the plurality of planar foils comprises a first face and a second face opposite the first face, the plurality of planar foils being arranged in a stack along a stacking direction, with the second face of each planar foil of the plurality of planar foils arranged on a first face of a respective preceding planar foil in the stack,
wherein the first face of each planar foil of the plurality of planar foils comprises a corresponding elongated trench extending substantially along a second direction that is perpendicular to the stacking direction, and
wherein, for each planar foil of the plurality of planar foils, a depth of the corresponding trench extends through less than an entire thickness of the planar foil.

2. The laser diode heat sink of claim 1, wherein a first side of the stack provides a laser diode mounting region, and wherein, for each planar foil of the plurality of planar foils, a portion of the trench extends in the second direction substantially alongside the laser diode mounting region.

3. The laser diode heat sink of claim 1, wherein the stack comprises a common fluid inlet port to which the corresponding trench of each planar foil of the plurality of planar foils is fluidly coupled, wherein the common fluid input port extends through the stack along the stacking direction.

4. The laser diode heat sink of claim 3, wherein the stack comprises a common fluid output port to which the corresponding trench of each planar foil of the plurality of planar foils is fluidly coupled, wherein the common fluid output port extends through the stack along the stacking direction.

5. The laser diode heat sink of claim 1, wherein the stack comprises:
at least two common fluid inlet ports to which the corresponding trench of each planar foil of the plurality of planar foils is fluidly coupled; and
a common fluid output port to which the corresponding trench of each planar foil of the plurality of planar foils is fluidly coupled,
wherein each of the at least two common fluid input ports and the common fluid output port extends through the stack along the stacking direction.

6. The laser diode heat sink of claim 1, comprising a dielectric layer on the first side of the stack.

7. The laser diode heat sink of claim 6, wherein the dielectric layer comprises an aluminum nitride layer.

8. The laser diode heat sink of claim 6, comprising at least one laser diode mounting pad on the dielectric layer.

9. The laser diode heat sink of claim 8, wherein the at least one laser diode mounting pad comprises a metal layer.

10. The laser diode heat sink of claim 8, comprising a plurality of laser diode mounting pads, wherein each laser diode mounting pad of the plurality of laser diode mounting pads is separated from an adjacent laser diode mounting pad by a corresponding gap.

11. The laser diode heat sink of claim 10, wherein each gap is elongated along the first side of the stack in the stacking direction.

12. The laser diode heat sink of claim 1, wherein, for each planar foil of the plurality of planar foils, the depth of the trench is less than or equal to about 150 microns.

13. The laser diode heat sink of claim 12, wherein a width of the trench is less than or equal to about 1 mm.

14. The laser diode heat sink of claim 1, wherein, for each planar foil of the plurality of planar foils, the thickness of the planar foil is less than or equal to about 300 microns.

15. The laser diode heat sink of claim 1, wherein the plurality of planar foils in the stack are aligned on top of one another so that the trench of each foil is aligned with and overlaps with a trench of an adjacent planar foil in the stack.

16. The laser diode heat sink of claim 1, wherein, for each planar foil of the plurality of planar foils, the trench has a bottom surface defined by the planar foil in which the trench is formed and a top surface defined by a face of an adjacent planar foil in the stack.

17. The laser diode heat sink of claim 1, wherein each planar foil of the plurality of foils is a copper foil.

18. The laser diode heat sink of claim 1, wherein the plurality of planar foils are welded together.

19. A laser diode apparatus comprising:
a first heat sink;
a second heat sink; and
at least one laser diode mounted between the first heat sink and the second heat sink,
wherein each of the first heat sink and the second heat sink comprises a corresponding plurality of foils arranged in a stack along a first direction, wherein each foil of the plurality of foils in the first heat sink and in the second heat sink comprises a generally planar first face and a generally planar second face opposite the first face with the second face of each foil arranged on a face of a respective preceding foil in the stack,
wherein the first face of each foil of the plurality of foils in the first heat sink and in the second heat sink comprises a corresponding elongated trench, and
wherein, for each foil of the plurality of foils in the first heat sink and in the second heat sink, a depth of the corresponding trench extends through less than an entire thickness of the foil.

20. A method of forming a laser diode heat sink, the method comprising:
providing a plurality of foils, wherein each foil of the plurality of foils comprises a generally planar first face and a generally planar second face opposite the first face, a distance between the first face and the second face defining a thickness of the foil;
forming in the first face of each foil of the plurality of foils, a corresponding trench, wherein a depth of the corresponding trench extends through less than the thickness of the foil; and
mounting the plurality of foils together into a stack along a first direction, with the second face of each foil of the plurality of foils arranged on a face of a respective preceding foil in the stack,
wherein, for each foil of the plurality of foils, the trench extends substantially along a second direction that is perpendicular to the first direction.

21. The method of claim 20, further comprising:
forming at least one common fluid input port in the stack, wherein the corresponding trench of each foil of the plurality of foils is fluidly coupled to the at least one common fluid input port, and wherein the at least one common fluid input port extends through the stack along the first direction; and
forming at least one common fluid output port in the stack, wherein the corresponding trench of each foil of the plurality of foils is fluidly coupled to the at least one common fluid output port, and wherein the at least one common fluid output port extends through the stack along the first direction.
